(19) United States
(12) Patent Application Publication
(10) Pub. No.: US 2007/0200584 A1
(43) Pub. Date: Aug. 30, 2007

(54) High frequency cantilever-type probe card

(75) Inventor: Wei-Cheng Ku, Hsinchu Hsiang (TW)

Correspondence Address: BROWDY AND NEIMARK, P.L.L.C.;624 NINTH STREET, NW, SUITE 300, WASHINGTON, DC, 20001-5303, US

(73) Assignee: MJC Probe Inc., Chu-PEI City (TW)

(21) Appl. No.: 11/704,331

(22) Filed: Feb. 9, 2007

(30) Foreign Application Priority Data
Aug. 4, 2005 (TW) 94126618

(51) Int. Cl. G01R 31/02

(52) U.S. Cl. 324/761

(57) ABSTRACT

A cantilever-type probe card includes a circuit board having a first surface on which a plurality of signal contact pads and grounding contact pads are formed, a locating ring mounted on the first surface of the circuit board, and a plurality of probe pins, each of which is partially supported by the locating ring. Each of the probe pins has an electrically conducting core having an exposed first end electrically connected to one of the signal contact pads of the circuit board, and an exposed second end suspending outside the locating ring for probing a test contact, and a metal film insulatively spaced from the electrically conducting core and electrically connected to one of the grounding contact pads of the circuit board.

### BACKGROUND OF THE INVENTION

1. Field of the Invention

The present invention relates generally probe cards and more particularly, to a cantilever-type probe card for high frequency application.

2. Description of the Related Art

In a regular probe card as shown in FIG. 1, each probe pin has a coaxial cable segment 1 and a probe pin segment 2 that are joined together by means of pin connection.

The configuration of the aforesaid coaxial cable segment provides a better signal impedance matching (anti-attenuation) effect. However, because the core wire strength of the coaxial cable segment is low, the coaxial cable segment is not suitable for probing. Therefore, it is necessary to connect a probe pin segment of relatively higher strength to one end of the coaxial cable segment by means of pin connection for probing. However, the junction between the coaxial cable segment and the probe pin segment tends to cause signal discontinuity (signal non-integrity).

To eliminate the aforesaid drawback, there are probe pin providers who arrange probe pin segments as a core of the coaxial cable, forming a coaxial cable configuration. This design provides an optimal signal impedance matching effect and eliminates the problem of signal discontinuity. However, it is expensive to arrange probe pins into a coaxial cable configuration for use as a core thereof. Further, this specification is a special product, not suitable for a mass application.

### SUMMARY OF THE INVENTION

The present invention has been accomplished under the circumstances in view. It is therefore one objective of the present invention to provide a cantilever-type probe card, which assures signal transmission integrity.

It is another objective of the present invention to provide a cantilever-type probe card, which is inexpensive to manufacture and easy to assembly.

To achieve these objectives of the present invention, the cantilever-type probe card comprises a circuit board having a first surface and a second surface opposite to the first surface, a locating ring mounted on the first surface of the circuit board, and a plurality of probe pins, each of which is partially supported by the locating ring and has a first end electrically connected to the first surface of the circuit board, and a second end suspending outside the locating ring for probing a test contact.

Each of the probe pins has an electrically conducting core with a first end electrically connected to one of signal contact pads formed on the first surface of the circuit board, and a second end suspending outside the locating ring for probing a test contact, and an electrically conducting member insulatively spaced from the electrically conducting core and electrically connected to one of grounding contact pads formed on the first surface of the circuit board. The electrically conducting core is partially coated with an electrically insulative film or is spacedly and partially sleeved thereon with an electrically insulative tube. The electrically conducting member can be a metal film coated on the electrically insulative film or the electrically insulative tube or a metal tube spacedly sleeved onto the electrically insulative film or the electrically insulative tube.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a schematic sectional view of a part of a cantilever-type probe card according to the prior art;

FIG. 2 is a schematic sectional view of a part of a cantilever-type probe card in accordance with a first preferred embodiment of the present invention;

FIG. 3 is a schematic cross-sectional view of a probe pin of the cantilever-type probe card in accordance with the first preferred embodiment of the present invention;

FIG. 4 is a schematic cross-sectional view of an alternate form of the probe pin;

FIG. 5 is schematic a cross-sectional view of another alternate form of the probe pin;

FIG. 6 is a schematic cross-sectional view of still another alternate form of the probe pin;

FIG. 7 is a schematic sectional view of a part of a cantilever-type probe card in accordance with a second preferred embodiment of the present invention;

FIG. 8 is a schematic sectional view of a part of a cantilever-type probe card in accordance with a third preferred embodiment of the present invention;

FIG. 9 is a schematic sectional view of a part of a cantilever-type probe card in accordance with a fourth preferred embodiment of the present invention;

FIG. 10 is a frequency characteristic plot obtained from a probe card according to the prior art, and

FIG. 11 is a frequency characteristic plot obtained from a cantilever-type probe card according to the first preferred embodiment of the present invention.

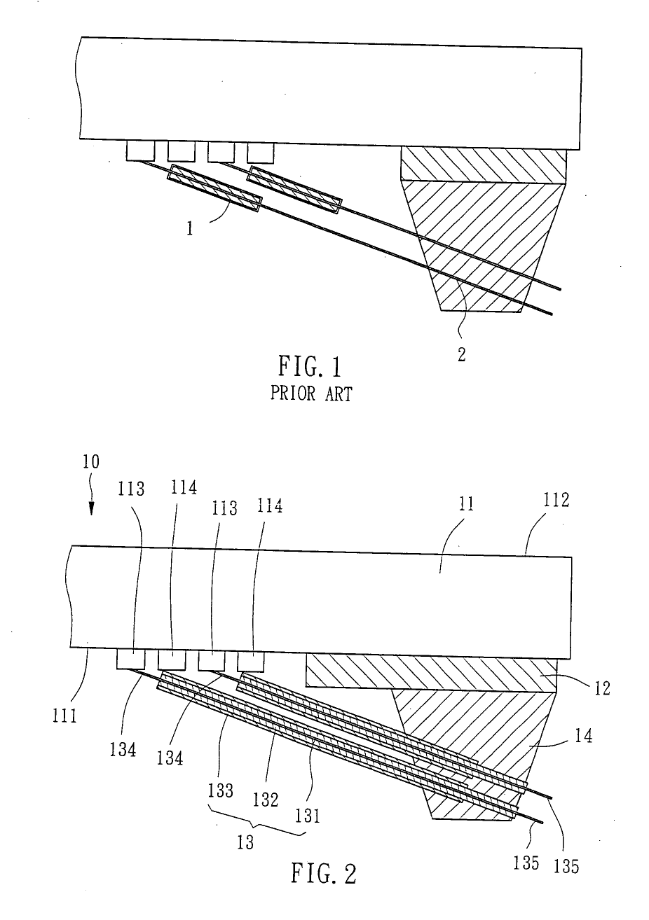

### DETAILED DESCRIPTION OF THE INVENTION

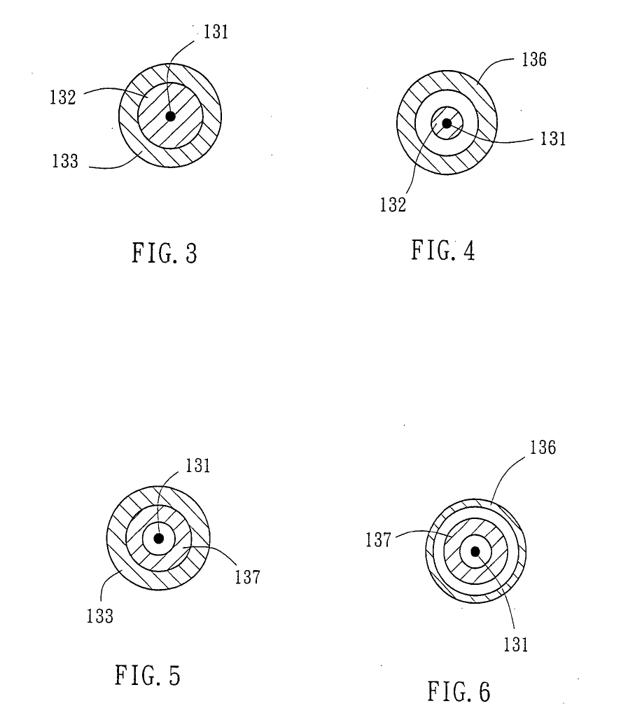

As shown in FIGS. 2 and 3, a high-frequency cantilever-type probe card 10 for probing semiconductor wafers or the like in accordance with a first preferred embodiment of the present invention comprises of a circuit board 11, a locating ring 12, a plurality of probe pins 13, and a bonding member 14.

The circuit board 11 defines a first surface 111 and a second surface 112 opposite to the first surface 111. The first surface 111 has formed thereon multiple metal contact pads including signal contact pads 113 and grounding contact pads 114. The second surface 112 has formed thereon a plurality of test contacts (not shown) respectively and electrically connected to the signal contact pads 113 and grounding contact pads 114 for connection to a tester electrically.

The locating ring 12 is installed on the first surface 111 of the circuit board 11. Further, the locating ring 12 is a metal member having excellent electrical conductivity for grounding.

The probe pins 13 each comprise an electrically conducting core 131 having a certain degree of strength and electrical conductivity, an electrically insulative film 132 partially coated on the outer surface of the electrically conducting core 131 by a sputtering technique, and a metal film 133 partially coated on the outer surface of the electrically insulative film 132 by a sputtering technique, such that the two distal ends of each electrically conducting core 131, namely, the first end 134 and the second end 135 are respectively exposed outside the electrically insulative film 132. The first ends 134 of the electrically conducting core 131 of the probe pins 13 are respectively and electrically connected to the signal contact pads 113 of the circuit board 11, and the metal films 133 of the probe pins 13 are respectively and electrically connected to grounding contact pads 114. By means of the aforesaid design, the probe pins are small-sized, and the probe card allows for installation of more number of probe pins in a relatively smaller area.

The bonding member 14 is electrically conductive, and adapted to affix a part of each probe pin 13 to the locating ring 12, allowing the second end 135 of the electrically conducting core 131 of each probe pin 13 to be exposed.

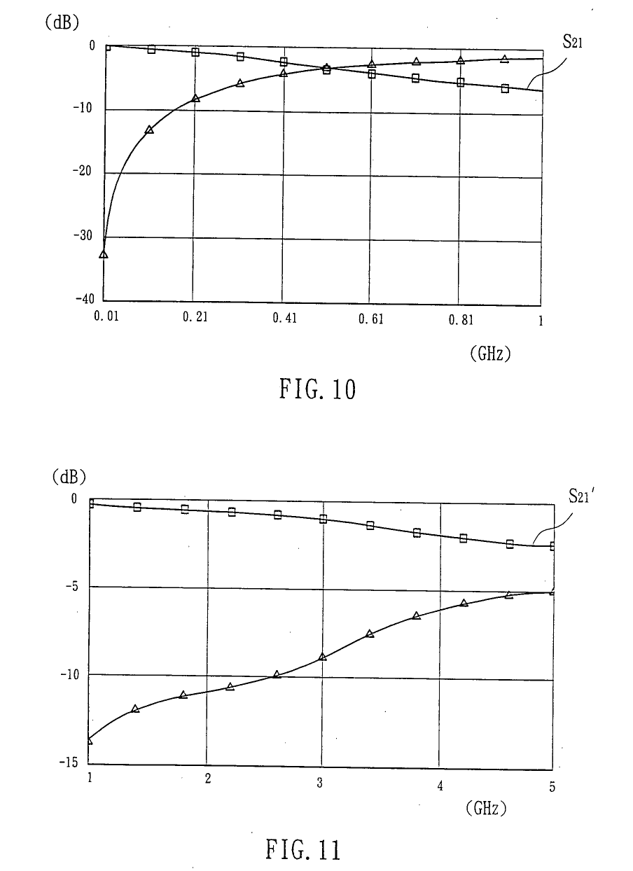

The above statement describes the main components of the high-frequency cantilever-type probe card 10 and their configuration. Based on the aforesaid structural design, the probe card has easy-to-manufacture and easy-to-assembly characteristics, thereby greatly reducing the cost. By means of the coaxial cable-like structure, signal is well isolated from interference. Further, this probe card structure can effectively increase the bandwidth of the signal. FIGS. 10 and 11 are the frequency characteristic plots respectively obtained from the invention and the prior art design. As illustrated, the signal insertion loss S21 of the prior art design provides a bandwidth of 500-600 MHz at −3 dB while the signal insertion loss S21′ of the present invention provides a bandwidth over 5 GHz. Therefore, the invention is suitable for high frequency testing.

FIGS. 4, 5 and 6 show different alternate forms of the probe pins for the high-frequency cantilever-type probe card 10 that achieve the same effects.

According to the design shown in FIG. 4, a metal tube 136 is axially spacedly sleeved onto the electrically insulative film 132 to substitute for the aforesaid metal film 133 (see also FIG. 3), and a gap exists in between the metal tube 136 and the electrically insulative film 132 for retaining air. This design achieves the same effects of the probe pins shown in FIG. 3.

According to the design shown in FIG. 5, an electrically insulative tube 137 is axially spacedly sleeved onto the electrically conducting core 131 to substitute for the aforesaid electrically insulative film 132 (see also FIG. 3), and a gap exists in between the electrically insulative tube 137 and the electrically conducting core 131 to retain air. This design achieves the same effects of the probe pins shown in FIG. 3.

According to the design shown in FIG. 6, an electrically insulative tube 137 and a metal tube 136 are used to substitute for the aforesaid electrically insulative film 132 and metal film 133 (see also FIG. 3), i.e., the electrically insulative tube 137 is axially spacedly sleeved onto the electrically conducting core 131 and the metal tube 136 is axially spacedly sleeved onto the electrically insulative tube 137. Further, gaps exist in between the metal tube 136 and the electrically insulative tube 137 and in between the electrically insulative tube 137 and the electrically conducting core 131 to retain air respectively. This design achieves the same effects of the probe pins shown in FIG. 3.

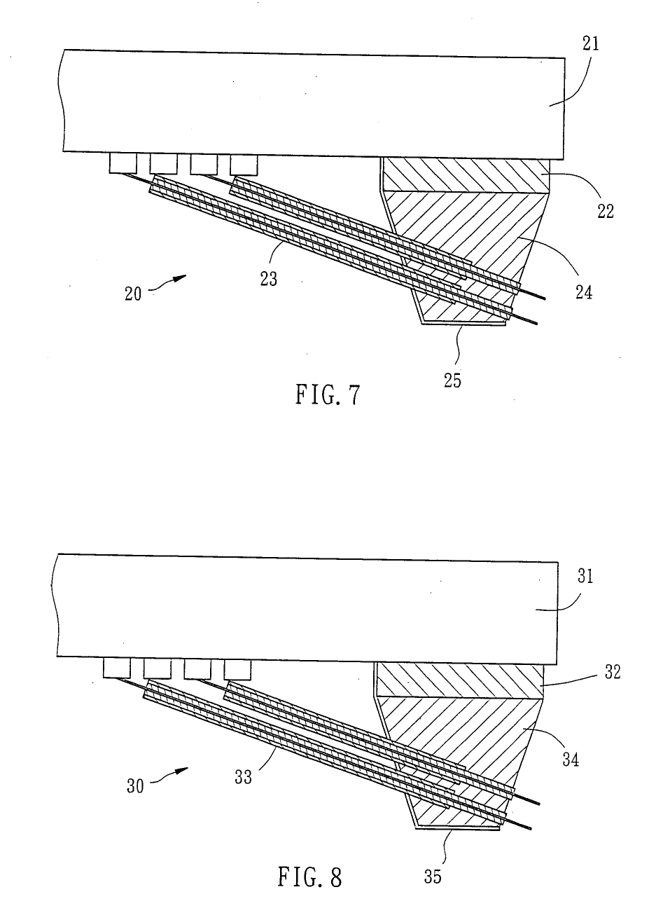

FIG. 7 shows a probe card 20 in accordance with a second preferred embodiment of the present invention. According to this embodiment, the probe card 20 comprises a circuit board 21, a locating ring 22, a plurality of probe pins 23, and a bonding member 24. This embodiment is substantially similar to the aforesaid first embodiment with the exception that the locating ring 22 and the bonding member 24 are respectively made from an electrically insulative material and respectively covered with a layer of metal film 25 for grounding.

FIG. 8 shows a probe card 20 in accordance with a third preferred embodiment of the present invention. According to this embodiment, the probe card 30 is comprised of a circuit board 31, a locating ring 32, a plurality of probe pins 33, and a bonding member 34. This embodiment is substantially similar to the aforesaid first embodiment with the exception that the locating ring 32 is made from an electrically conductive material and the bonding member 34 is made from an electrically insulative material. In addition, the locating ring 32 and the bonding member 34 are peripherally partially covered with a layer of metal film 25 for grounding.

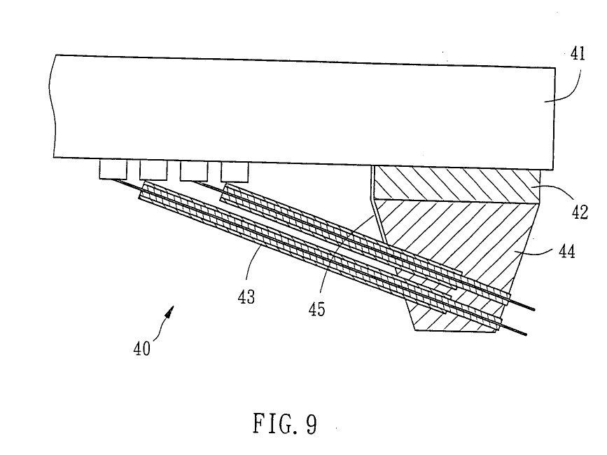

FIG. 9 shows a probe card 40 in accordance with a fourth preferred embodiment of the present invention. According to this embodiment, the probe card 40 comprises a circuit board 41, a locating ring 42, a plurality of probe pins 43, and a bonding member 44. This embodiment is substantially similar to the aforesaid first embodiment with the exception that the locating ring 42 is made from an electrically insulative material and the bonding member 44 is made from an electrically conductive material. In addition, the locating ring 42 and the bonding member 44 are peripherally partially covered with a layer of metal film 45 for grounding.

What is claimed is:

1. A cantilever-type probe card comprising:
a circuit board having a first surface and a second surface opposite to the first surface;
a locating ring mounted on the first surface of the circuit board; and
a plurality of probe pins, each of which is partially supported by the locating ring and has a first end electrically connected to the first surface of the circuit board, and a second end suspending outside the locating ring for probing a test contact.

2. The cantilever-type probe card as claimed in claim 1, wherein the second surface of the circuit board is provided thereon a plurality of test contacts respectively electrically connected to the probe pins for connection to a tester.

3. The cantilever-type probe card as claimed in claim 1, wherein the first surface of the circuit board is provided thereon a plurality of metal contact pads for the connection of the first ends of the probe pins.

4. The cantilever-type probe card as claimed in claim 1, wherein each of the probe pins comprises an electrically conducting core, an electrically insulative tube spacedly and partially sleeved onto the electrically conducting core such that two distal ends of the electrically conducting core are exposed outside the electrically insulative tube to form the first end and the second end of the probe pin respectively and a gap is defined between the electrically conducting core and the electrically insulative tube to retain air, and a metal tube spacedly sleeved onto the electrically insulative tube such that a gap is defined between the electrically insulative tube and the metal tube to retain air.

5. The cantilever-type probe card as claimed in claim 4, wherein the first surface of the circuit board comprises a plurality of signal contact pads and grounding contact pads; the first ends of the probe pins are respectively electrically connected to the signal contact pads of the circuit board; the metal tubes of the probe pins are respectively electrically connected to the grounding contact pads.

6. The cantilever-type probe card as claimed in claim 1, wherein each of the probe pins comprises an electrically conducting core, an electrically insulative tube spacedly and partially sleeved onto the electrically conducting core such that two distal ends of the electrically conducting core are exposed outside the electrically insulative tube to form the first end and the second end of the probe pin respectively and a gap is defined between the electrically conducting core and the electrically insulative tube to retain air, and a metal film coated on a periphery of the electrically insulative tube.

7. The cantilever-type probe card as claimed in claim 6, wherein the first surface of the circuit board comprises a plurality of signal contact pads and grounding contact pads; the first ends of the probe pins are respectively electrically connected to the signal contact pads of the circuit board; the metal films of the probe pins are respectively electrically connected to the grounding contact pads.

8. The cantilever-type probe card as claimed in claim 1, wherein each of the probe pins comprises an electrically conducting core, an electrically insulative film partially coated on a periphery of the electrically conducting core in such a manner that two distal ends of the electrically conducting core are exposed outside the electrically insulative film to form the first end and the second end of the probe pin respectively, and a metal tube spacedly sleeved onto the electrically insulative film such that a gap is defined between the electrically insulative film and the metal tube to retain air.

9. The cantilever-type probe card as claimed in claim 8, wherein the first surface of the circuit board comprises a plurality of signal contact pads and grounding contact pads; the first ends of the probe pins are respectively electrically connected to the signal contact pads of the circuit board; the metal tubes of the probe pins are respectively electrically connected to the grounding contact pads.

10. The cantilever-type probe card as claimed in claim 8, wherein each of the probe pins comprises an electrically conducting core, an electrically insulative film partially coated on a periphery of the electrically conducting core in such a manner that two distal ends of the electrically conducting core are exposed outside the electrically insulative film to form the first end and the second end of the probe pin respectively, and a metal film coated on a periphery of the electrically insulative film.

11. The cantilever-type probe card as claimed in claim 10, wherein the first surface of the circuit board comprises a plurality of signal contact pads and grounding contact pads; the first ends of the probe pins are respectively electrically connected to the signal contact pads of the circuit board; the metal films of the probe pins are respectively electrically connected to the grounding contact pads.

12. The cantilever-type probe card as claimed in claim 1, wherein the locating ring is bonded thereto with a bonding member that supports the probe pins; wherein the locating ring and the bonding member are electrically conductive and the locating ring is used for grounding.

13. The cantilever-type probe card as claimed in claim 1, wherein the locating ring is bonded thereto with a bonding member that supports the probe pins; wherein the locating ring and the bonding member are electrically insulative and peripherally partially surrounded by a layer of metal film for grounding.

14. The cantilever-type probe card as claimed in claim 1, wherein the locating ring is bonded thereto with a bonding member that supports the probe pins; wherein the locating ring is electrically conductive, the bonding member is electrically insulative and the locating ring and the bonding member are peripherally partially surrounded by a layer of metal film for grounding.

15. The cantilever-type probe card as claimed in claim 1, wherein the locating ring is bonded thereto with a bonding member that supports the probe pins; wherein the locating ring is electrically insulative, the bonding member is electrically conductive and the locating ring and the bonding member are peripherally partially surrounded by a layer of metal film for grounding.
